(19) United States
(12) Patent Application Publication
(10) Pub. No.: US 2024/0145412 A1
(43) Pub. Date: May 2, 2024

(54) SEMICONDUCTOR DEVICE

(71) Applicant: UNITED MICROELECTRONICS CORP., Hsin-Chu City (TW)

(72) Inventors: Shih-Che Huang, Chiayi City (TW); Chao-Ting Chen, Tainan City (TW); Jui-Fa Lu, Tainan City (TW); Chi-Heng Lin, Hsinchu City (TW)

(73) Assignee: UNITED MICROELECTRONICS CORP., Hsin-Chu City (TW)

(21) Appl. No.: 17/994,382

(22) Filed: Nov. 27, 2022

(30) Foreign Application Priority Data
Oct. 31, 2022 (TW) 111141395

(51) Int. Cl. H01L 23/60; H01L 23/522

(52) U.S. Cl. CPC H01L 23/60; H01L 23/5221; H01L 23/5226

(57) ABSTRACT

A semiconductor device includes a logic circuit region having at least one core device and at least one input/output (I/O) device. The at least one core device has a first accumulative antenna ratio, and the at least one I/O device has a second accumulative antenna ratio. The first accumulative antenna ratio is greater than the second accumulative antenna ratio.

### BACKGROUND OF THE INVENTION

### 1. Field of the Invention

The invention relates to the field of semiconductor technology, in particular to an improved semiconductor device capable of eliminating or mitigating plasma-induced damage (PID).

### 2. Description of the Prior Art

The “antenna effect” is a common name for the effects of charge accumulation in isolated nodes of an integrated circuit during its processing. This effect is also sometimes called “Plasma Induced Damage” (PID). In those cases that the discharging of the isolated nodes is done through the thin gate oxide of the transistor, it might cause damage to the transistors and degrade their performance.

In order to prevent this residual accumulation from damaging circuits, IC manufacturers have defined several types of design rules. The most common rule is called “antenna ratio”. This rule applies to any metal pattern connected to a gate of a transistor. It defines a limit for the ratio between the area (or the peripheral length) of the metal and the area of the gate oxide of the gate to which the metal is attached. This rule tends to limit the amount of charge that might stress the victim gate oxide.

However, the existing design rules do not provide complete elimination of PID.

### SUMMARY OF THE INVENTION

One object of the present invention is to provide an improved semiconductor device to solve the deficiencies or shortcomings of the prior art.

One aspect of the invention provides a semiconductor device including a logic circuit region comprising at least one core device and at least one input/output (I/O) device, wherein the at least one core device has a first accumulative antenna ratio, and the at least one I/O device has a second accumulative antenna ratio, and wherein the first accumulative antenna ratio is greater than the second accumulative antenna ratio.

According to some embodiments, the first accumulative antenna ratio is smaller than or equal to 5500.

According to some embodiments, the at least one I/O device is 1.8V I/O device and the second accumulative antenna ratio is smaller than or equal to 1000.

According to some embodiments, the 1.8V I/O device has a first single-layer antenna ratio of smaller than or equal to 500.

According to some embodiments, the at least one I/O device is 2.5V I/O device and the second accumulative antenna ratio is smaller than or equal to 2000.

According to some embodiments, the 2.5V I/O device has a second single-layer antenna ratio of smaller than or equal to 600.

According to some embodiments, the at least one core device comprises a first metal gate and a first gate oxide layer having a thickness that is equal to or less than 15 angstroms.

According to some embodiments, the at least one I/O device comprises a second metal gate and a second gate oxide layer having a thickness that is equal to or less than 50 angstroms.

According to some embodiments, the semiconductor device further comprises an embedded high-voltage circuit region comprising at least one high-voltage device, wherein the at least one high-voltage device has a third accumulative antenna ratio of smaller than or equal to 2000 and a third single-layer antenna ratio of smaller than or equal to 1000.

According to some embodiments, the at least one high-voltage device comprises a third gate oxide layer having a thickness that is equal to or greater than 500 angstroms.

Another aspect of the invention provides a semiconductor device including a substrate having a logic circuit region thereon; at least one core device disposed on the substrate within the logic circuit region, wherein the at least one core device has a first metal gate; a first interconnect structure electrically connected to the first metal gate; at least one input/output (I/O) device disposed on the substrate within the logic circuit region, wherein the at least one I/O device has a second metal gate; a second interconnect structure electrically connected to the second metal gate, wherein the second interconnect structure comprises a single metal layer having surface area greater than other layers of the second interconnect structure, and wherein the single metal layer is separated into a first portion and a second portion; and a jumper structure overlying the single metal layer for bridging the first portion with the second portion.

According to some embodiments, the first portion has a surface area that is smaller than that of the second portion.

According to some embodiments, the jumper structure comprises an upper metal layer, a first via connecting the upper metal layer to the first portion, and a second via connecting the upper metal layer to the second portion.

According to some embodiments, the at least one core device has a first accumulative antenna ratio, and the at least one I/O device has a second accumulative antenna ratio, and wherein the first accumulative antenna ratio is greater than the second accumulative antenna ratio. According to some embodiments, the first accumulative antenna ratio is smaller than or equal to 5500.

According to some embodiments, the at least one I/O device is 1.8V I/O device and the second accumulative antenna ratio is smaller than or equal to 1000.

According to some embodiments, the 1.8V I/O device has a first single-layer antenna ratio of smaller than or equal to 500.

According to some embodiments, the at least one I/O device is 2.5V I/O device and the second accumulative antenna ratio is smaller than or equal to 2000.

According to some embodiments, the 2.5V I/O device has a second single-layer antenna ratio of smaller than or equal to 600.

According to some embodiments, the at least one core device comprises a first gate oxide layer having a thickness that is equal to or less than 15 angstroms, and the at least one I/O device comprises a second gate oxide layer having a thickness that is equal to or less than 50 angstroms.

According to some embodiments, the semiconductor device further includes an embedded high-voltage circuit region comprising at least one high-voltage device, wherein the at least one high-voltage device has a third accumulative antenna ratio of smaller than or equal to 2000 and a third single-layer antenna ratio of smaller than or equal to 1000.

According to some embodiments, the at least one high-voltage device comprises a third gate oxide layer having a thickness that is equal to or greater than 500 angstroms.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a semiconductor device according to an embodiment of the present invention.

FIG. 2 is a schematic diagram of a semiconductor device according to another embodiment of the present invention.

FIG. 3 is a schematic diagram of a semiconductor device according to yet another embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

In the process of manufacturing the metal layers (interconnection or metal gates), the metal layers exposed to the plasma act like an antenna and collect the free charges in the plasma. When the charge on the metal layers is too much, causing the electric field of the gate oxide layer connected to the metal layer to be too high, it will break down the gate oxide layer and cause device reliability problems.

High-k/metal-gate transistors have been introduced into advanced complementary metal-oxide-semiconductor (CMOS) technology to replace SiO₂/poly-gate transistors in suppressing the gate leakage current and eliminating poly depletion effect. In advanced hafnium-based high-k metal gate (HK/MG) technologies, plasma induced damage during process is unavoidable and has the potential to degrade device performance and gate dielectrics.

The present invention proposes a solution to overcome the above-mentioned problems. Hereinafter, the antenna ratio is defined as the area ratio between the metal interconnection and the gate to which it is attached, and is applicable to the metal wiring pattern of each layer connected to the gate of the transistor. If only the area ratio between the single-layer metal wire area and the gate is calculated, it is called the single-layer antenna ratio. The accumulated antenna ratio is the sum of the single-layer antenna ratios.

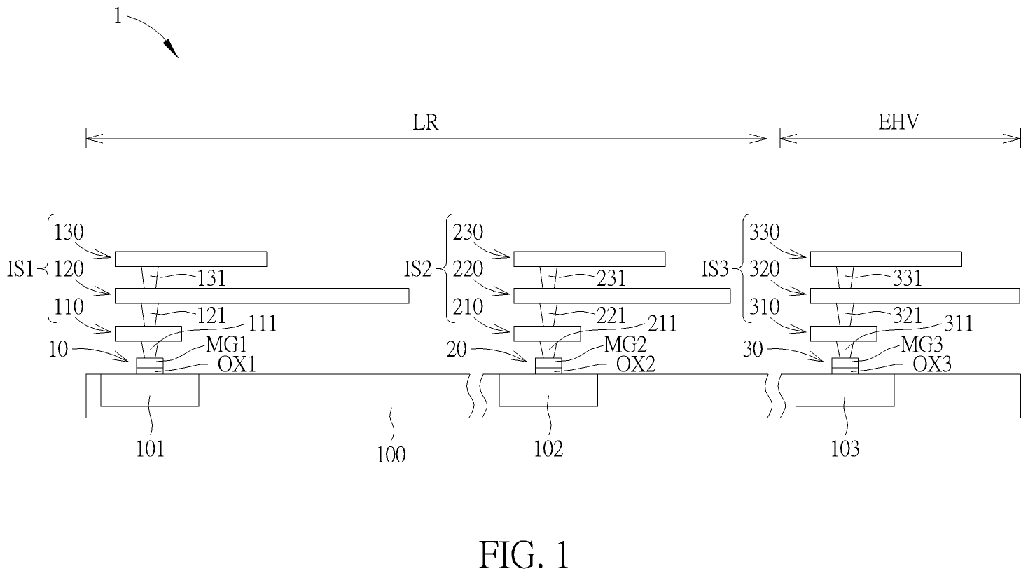

Please refer to FIG. 1, which is a schematic diagram of a semiconductor device according to an embodiment of the present invention. As shown in FIG. 1, the semiconductor device 1 includes a logic circuit region LR including at least one core device 10 and at least one input/output (I/O) device 20. According to an embodiment of the present invention, the semiconductor device 1 further includes an embedded high voltage circuit region EHV including at least one high voltage device 30. According to an embodiment of the present invention, the core device 10, the I/O device 20 and the high voltage device 30 may be respectively disposed on the ion well 101, the ion well 102 and the ion well 103 of the semiconductor substrate 100. According to an embodiment of the present invention, the ion well 101, the ion well 102 and the ion well 103 may be P-type wells or N-type wells.

According to an embodiment of the present invention, the core device 10 includes a first metal gate MG1 and a first gate oxide layer OX1, wherein the thickness of the first gate oxide layer OX1 is less than or equal to 15 angstroms. According to an embodiment of the present invention, the I/O device 20 includes a second metal gate MG2 and a second gate oxide layer OX2, wherein the thickness of the second gate oxide layer OX2 is less than or equal to 50 angstroms. According to an embodiment of the present invention, the high voltage device 30 includes a third metal gate MG3 and a third gate oxide layer OX3, wherein the thickness of the third gate oxide layer OX3 is greater than or equal to 500 angstroms.

According to an embodiment of the present invention, the semiconductor device 1 further includes a first interconnection structure IS1 connected to the first metal gate MG1, e including, for example, a metal wire 110, a via 111 electrically connecting the metal wire 110 with the first metal gate MG1, a metal wire 120, a via 121 electrically connecting the metal wire 120 with the metal wire 110, a metal wire 130, and a via 131 electrically connecting the metal wire 130 with the metal wire 120.

According to an embodiment of the present invention, the semiconductor device 1 further includes a second interconnection structure IS2 connected to the second metal gate MG2, including, for example, a metal wire 210, a via 211 electrically connecting the metal wire 210 with the second metal gate MG2, the metal wire 220, the via 221 electrically connecting the metal wire 220 with the metal wire 210, the metal wire 230, the via 231 electrically connecting the metal wire 230 with the metal wire 220.

According to an embodiment of the present invention, the semiconductor device 1 further includes a third interconnection structure IS3 connected to the third metal gate MG3, including, for example, a metal wire 310, a via 311 electrically connecting the metal wire 310 with the third metal gate MG3, a metal wire 320, a via 321 electrically connecting the metal wire 320 with the metal wire 310, a metal wire 330, and a via 331 electrically connecting the metal wire 330 with the metal wire 320. The number of metal layers in the figure is for illustrative purposes only.

According to an embodiment of the present invention, the core device 10 has a first accumulative antenna ratio CAR1, which is a ratio of the metal area of the first interconnection structure IS1 connected to the first metal gate MG1 to the area of the first metal gate MG1. According to an embodiment of the present invention, the first accumulative antenna ratio CAR1 is less than or equal to 5500. According to an embodiment of the present invention, the I/O device 20 has a second accumulative antenna ratio CAR2, wherein the first accumulative antenna ratio CAR1 is greater than the second accumulative antenna ratio CAR2.

According to an embodiment of the present invention, the I/O device 20 is a 1.8V I/O device, and the second accumulative antenna ratio CAR2 is less than or equal to 1000. According to an embodiment of the present invention, the I/O device 20 is a 1.8V I/O device having a first single-layer antenna ratio SAR1, which is the ratio of the surface area of a single metal layer of the second interconnection structure IS2 such as the metal wire 220 connected to the second metal gate MG2 to the surface area of the second metal gate MG2. In this example, the surface area of the metal wire 220 is greater than the metal area of any other layer of the second interconnection structure IS2. According to an embodiment of the present invention, the first single-layer antenna ratio SAR1 is less than or equal to 500.

According to an embodiment of the present invention, the I/O device is a 2.5V I/O device, and the second accumulative antenna ratio CAR2 is less than or equal to 2000. According to an embodiment of the present invention, the I/O device is a 2.5V I/O device having a second single-layer antenna ratio SAR2. According to an embodiment of the present invention, the second single-layer antenna ratio SAR2 is less than or equal to 600.

According to an embodiment of the present invention, the high voltage device 30 has a third accumulative antenna ratio CAR3 and a third single-layer antenna ratio SAR3. The third single-layer antenna ratio SAR3 is the ratio of the surface area of a single metal layer of the third interconnection structure IS3 such as the metal wire 320 connected to the third metal gate MG3 to the surface area of the third metal gate MG3. In this example, the surface area of the metal wire 320 is larger than any other layer of the third interconnection structure IS3. According to an embodiment of the present invention, the third accumulative antenna ratio CAR3 is less than or equal to 2000, and the third single-layer antenna ratio SAR3 is less than or equal to 1000.

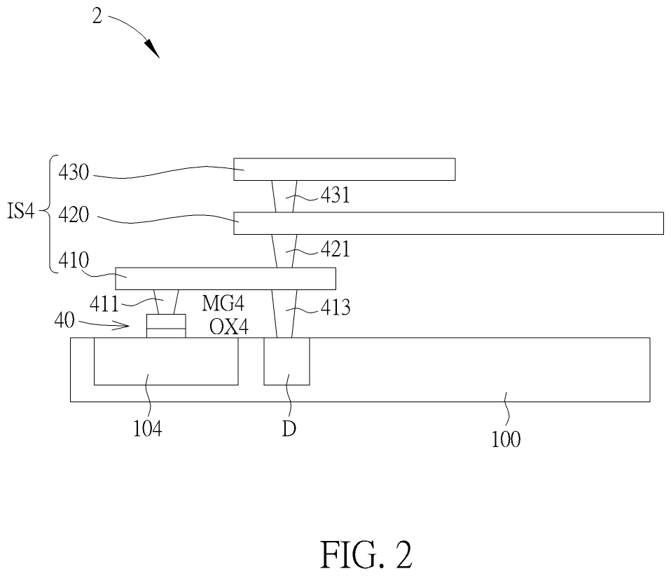

Please refer to FIG. 2, which is a schematic diagram of a semiconductor device according to another embodiment of the present invention. As shown in FIG. 2, the semiconductor device 2 includes a transistor device 40 disposed on a semiconductor substrate 100. According to an embodiment of the present invention, the transistor device 40 may be disposed on the ion well 104 of the semiconductor substrate 100. According to an embodiment of the present invention, the ion well 104 may be a P-type well or an N-type well. According to an embodiment of the present invention, the transistor device 40 includes a fourth metal gate MG4 and a fourth gate oxide layer OX4.

According to an embodiment of the present invention, the semiconductor device 2 further includes a fourth interconnection structure IS4 connected to the fourth metal gate MG4, including, for example, a metal wire 410, a via 411 electrically connecting the metal wire 410 with the fourth metal gate MG4, a metal wire 420, a via 421 electrically connecting the metal wire 420 with the metal wire 410, a metal wire 430, and a via 431 electrically connecting the metal wire 430 with the metal wire 420. In order to protect the fourth metal gate MG4 and the fourth gate oxide layer OX4, the metal wire 410 can be connected to the diode D through the via (or contact) 413, so that the charge can be shunted to the substrate 100 to reduce charge accumulation.

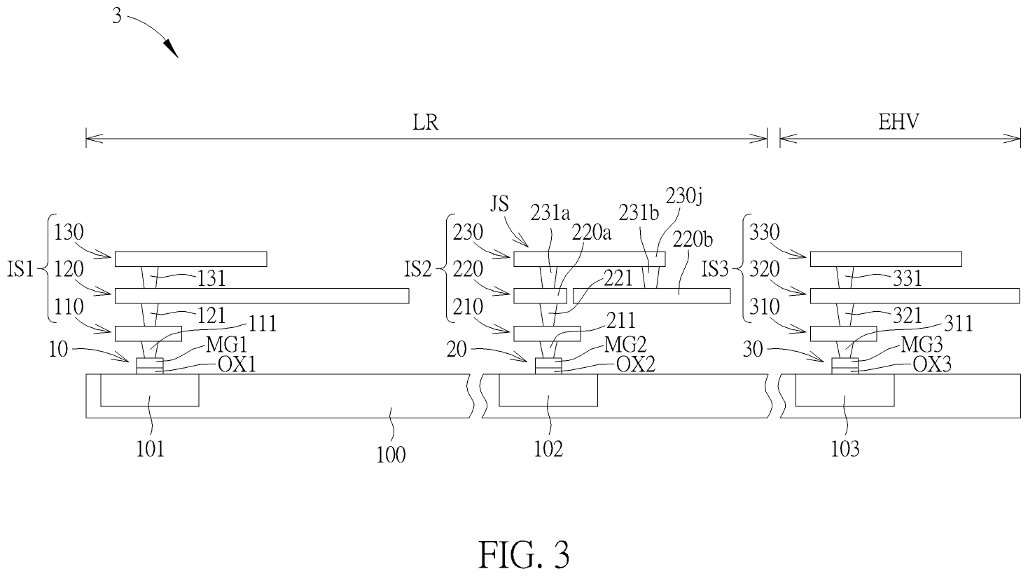

Please refer to FIG. 3, which is a schematic diagram of a semiconductor device according to yet another embodiment of the present invention. As shown in FIG. 3, likewise, the semiconductor device 3 includes a substrate 100 with a logic circuit region LR thereon. At least one core device 10 is disposed on the substrate 100 in the logic circuit region LR. The core device 10 has a first metal gate MG1. The semiconductor device 3 further includes a first interconnect structure IS1 electrically connected to the first metal gate MG1. The semiconductor device 3 also includes at least one I/O device 20 disposed on the substrate 100 in the logic circuit region LR. The I/O device 20 has a second metal gate MG2. The semiconductor device 3 further includes a second interconnect structure IS2 electrically connected to the second metal gate MG2. According to an embodiment of the present invention, the core device 10 includes a first gate oxide layer OX1 with a thickness less than or equal to 15 angstroms, and the I/O device 20 includes a second gate oxide layer OX2 with a thickness less than or equal to 50 angstroms.

According to an embodiment of the present invention, the second interconnection structure IS2 includes a single metal layer having a surface area larger than any other layer of the second interconnection structure IS2, for example, a metal wire 220, which is divided into a first portion 220a and a second portion 220b. The discontinuity between the first portion 220a and the second portion 220b is located closer to the I/O device 20. According to an embodiment of the present invention, the semiconductor device 2 further includes a jumper structure JS disposed on the metal wire 220 for bridging the first portion 220a and the second portion 220b. According to an embodiment of the present invention, the surface area of the first portion 220a is smaller than the surface area of the second portion 220b. According to an embodiment of the present invention, the jumper structure JS includes an upper metal layer 230j, a first via 231a connecting the upper metal layer 230j to the first portion 220a, and a second via 231b connecting the upper metal layer 230j to the second portion 220b.

According to an embodiment of the present invention, the core device 10 has a first accumulative antenna ratio CAR1, and the I/O device 20 has a second accumulative antenna ratio CAR2, wherein the first accumulative antenna ratio CAR1 is greater than the second accumulative antenna ratio CAR2. According to an embodiment of the present invention, the first accumulative antenna ratio CAR1 is less than or equal to 5500.

According to an embodiment of the present invention, the I/O device 20 is a 1.8V I/O device, and the second accumulative antenna ratio CAR2 is less than or equal to 1000. According to an embodiment of the present invention, the I/O device 20 is a 1.8V I/O device having a first single-layer antenna ratio SAR1, which is the ratio of the surface area of a single metal layer of the second interconnection structure IS2 such as the metal wire 220 connected to the second metal gate MG2 to the surface area of the second metal gate MG2. In this example, the surface area of the metal wire 220 is greater than the metal area of any other layer of the second interconnection structure IS2. According to an embodiment of the present invention, the first single-layer antenna ratio SAR1 is less than or equal to 500.

According to an embodiment of the present invention, the I/O device is a 2.5V I/O device, and the second accumulative antenna ratio CAR2 is less than or equal to 2000. According to an embodiment of the present invention, the I/O device is a 2.5V I/O device having a second single-layer antenna ratio SAR2. According to an embodiment of the present invention, the second single-layer antenna ratio SAR2 is less than or equal to 600.

According to an embodiment of the present invention, the semiconductor device 3 may include an embedded high-voltage circuit region EHV, including at least one high-voltage device 30. The high-voltage device 30 has a third accumulative antenna ratio CAR3 and a third single-layer antenna ratio SAR3. The third accumulative antenna ratio CAR3 is less than or equal to 2000, and the third single-layer antenna ratio SAR3 is less than or equal to 1000. According to an embodiment of the present invention, the high voltage device 30 has a third gate oxide layer OX3 with a thickness greater than or equal to 500 angstroms.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a logic circuit region comprising at least one core device and at least one input/output (I/O) device, wherein the at least one core device has a first accumulative antenna ratio, and the at least one I/O device has a second accumulative antenna ratio, and wherein the first accumulative antenna ratio is greater than the second accumulative antenna ratio.

2. The semiconductor device according to claim 1, wherein the first accumulative antenna ratio is smaller than or equal to 5500.

3. The semiconductor device according to claim 2, wherein the at least one I/O device is 1.8V I/O device and the second accumulative antenna ratio is smaller than or equal to 1000.

4. The semiconductor device according to claim 3, wherein the 1.8V I/O device has a first single-layer antenna ratio of smaller than or equal to 500.

5. The semiconductor device according to claim 2, wherein the at least one I/O device is 2.5V I/O device and the second accumulative antenna ratio is smaller than or equal to 2000.

6. The semiconductor device according to claim 5, wherein the 2.5V I/O device has a second single-layer antenna ratio of smaller than or equal to 600.

7. The semiconductor device according to claim 1, wherein the at least one core device comprises a first metal gate and a first gate oxide layer having a thickness that is equal to or less than 15 angstroms.

8. The semiconductor device according to claim 7, wherein the at least one I/O device comprises a second metal gate and a second gate oxide layer having a thickness that is equal to or less than 50 angstroms.

9. The semiconductor device according to claim 1 further comprising:
an embedded high-voltage circuit region comprising at least one high-voltage device, wherein the at least one high-voltage device has a third accumulative antenna ratio of smaller than or equal to 2000 and a third single-layer antenna ratio of smaller than or equal to 1000.

10. The semiconductor device according to claim 9, wherein the at least one high-voltage device comprises a third gate oxide layer having a thickness that is equal to or greater than 500 angstroms.

11. A semiconductor device, comprising:
a substrate having a logic circuit region thereon;
at least one core device disposed on the substrate within the logic circuit region, wherein the at least one core device has a first metal gate;
a first interconnect structure electrically connected to the first metal gate;
at least one input/output (I/O) device disposed on the substrate within the logic circuit region, wherein the at least one I/O device has a second metal gate;
a second interconnect structure electrically connected to the second metal gate, wherein the second interconnect structure comprises a single metal layer having surface area greater than other layers of the second interconnect structure, and wherein the single metal layer is separated into a first portion and a second portion; and
a jumper structure overlying the single metal layer for bridging the first portion with the second portion.

12. The semiconductor device according to claim 11, wherein the first portion has a surface area that is smaller than that of the second portion.

13. The semiconductor device according to claim 11, wherein the jumper structure comprises an upper metal layer, a first via connecting the upper metal layer to the first portion, and a second via connecting the upper metal layer to the second portion.

14. The semiconductor device according to claim 11, wherein the at least one core device has a first accumulative antenna ratio, and the at least one I/O device has a second accumulative antenna ratio, and wherein the first accumulative antenna ratio is greater than the second accumulative antenna ratio.

15. The semiconductor device according to claim 14, wherein the first accumulative antenna ratio is smaller than or equal to 5500.

16. The semiconductor device according to claim 15, wherein the at least one I/O device is 1.8V I/O device and the second accumulative antenna ratio is smaller than or equal to 1000.

17. The semiconductor device according to claim 16, wherein the 1.8V I/O device has a first single-layer antenna ratio of smaller than or equal to 500.

18. The semiconductor device according to claim 14, wherein the at least one I/O device is 2.5V I/O device and the second accumulative antenna ratio is smaller than or equal to 2000.

19. The semiconductor device according to claim 18, wherein the 2.5V I/O device has a second single-layer antenna ratio of smaller than or equal to 600.

20. The semiconductor device according to claim 11, wherein the at least one core device comprises a first gate oxide layer having a thickness that is equal to or less than 15 angstroms, and the at least one I/O device comprises a second gate oxide layer having a thickness that is equal to or less than 50 angstroms.

21. The semiconductor device according to claim 14 further comprising:
an embedded high-voltage circuit region comprising at least one high-voltage device, wherein the at least one high-voltage device has a third accumulative antenna ratio of smaller than or equal to 2000 and a third single-layer antenna ratio of smaller than or equal to 1000.

22. The semiconductor device according to claim 21, wherein the at least one high-voltage device comprises a third gate oxide layer having a thickness that is equal to or greater than 500 angstroms.
